(19) United States
(12) Patent Application Publication
(10) Pub. No.: US 2025/0072205 A1
(43) Pub. Date: Feb. 27, 2025

(54) LIGHT EMITTING ELEMENT AND DISPLAY DEVICE INCLUDING THE SAME

(71) Applicant: Samsung Display Co., LTD., Yongin-si (KR)

(72) Inventors: Hye Won CHOI, Yongin-si (KR); Dae Woong LEE, Yongin-si (KR); Hyeong Pil KIM, Yongin-si (KR); Il Soo OH, Yongin-si (KR)

(21) Appl. No.: 18/739,214

(22) Filed: Jun. 10, 2024

(30) Foreign Application Priority Data
Aug. 23, 2023 (KR) 10-2023-0110812

(51) Int. Cl. H10K 50/19; H10K 50/13; H10K 101/30; H10K 101/40; H10K 102/00

(52) U.S. Cl. CPC H10K 50/19; H10K 50/131; H10K 2101/30; H10K 2101/40; H10K 2102/351

(57) ABSTRACT

A light emitting element includes an anode electrode, a cathode electrode facing the anode electrode, and a light emitting structure provided between the anode electrode and the cathode electrode, and including a first light emitting unit, a charge generation layer, and a second light emitting unit. The second light emitting unit includes a second hole transport unit provided on the charge generation layer, a second light emitting layer provided on the second hole transport unit, an intermediate layer provided on the second light emitting layer, a third light emitting layer provided on the intermediate layer, and a second electron transport unit provided between the third light emitting layer and the cathode electrode.

### CROSS-REFERENCE TO RELATED APPLICATION

This application claims priority to and the benefit of Korean Patent Application No. 10-2023-0110812, filed on Aug. 23, 2023, in the Korean Intellectual Property Office, the entire content of which is incorporated herein by reference.

### BACKGROUND

### 1. Field

The disclosure relates to a light emitting element and a display device including the light emitting element.

### 2. Description of the Related Art

As information technology develops, importance of a display device, which is a connection medium between a user and corresponding information, has been highlighted.

A display device includes a plurality of light emitting elements. The light emitting element may be to emit light, for example, when a hole from an anode electrode and an electron injected from a cathode electrode in a light emitting layer recombine to generate an exciton, which transitions (e.g., relaxes, from an excited state to a ground state) to emit light.

Implementation of light-emitting elements to display devices requires (or there is a desire for), improvements in light efficiency, lifespan, and the like. Therefore, the need or desire exists for the development of materials for a light-emitting element capable of stably achieving such characteristics or desires.

### SUMMARY

One or more aspects of embodiments of the present disclosure is directed toward a light emitting element with improved efficiency and a desired roll-off characteristic and a display device including the light emitting element. Additional aspects will be set forth in part in the description which follows and, in part, will be apparent from the description, or may be learned by practice of the presented embodiments of the disclosure.

According to some embodiments of the disclosure, a light emitting element may include an anode electrode, a cathode electrode facing the anode electrode, and a light emitting structure provided between the anode electrode and the cathode electrode, and including a first light emitting unit, a charge generation layer, and a second light emitting unit. The second light emitting unit may include a second hole transport unit provided on the charge generation layer, a second light emitting layer provided on the second hole transport unit, an intermediate layer provided on the second light emitting layer, a third light emitting layer provided on the intermediate layer, and a second electron transport unit provided between the third light emitting layer and the cathode electrode.

The first light emitting unit may include a first hole transport unit provided on the anode electrode, a first electron transport unit facing the first hole transport unit and adjacent to the charge generation layer, and a first light emitting layer provided between the first hole transport unit and the first electron transport unit.

The entire thickness of the second light emitting layer, the intermediate layer, and the third light emitting layer may be 300 to 500 angstrom (Å).

A thickness of the intermediate layer may be 5 to 30 Å.

A lowest unoccupied molecular orbital (LUMO) energy level of the intermediate layer may be higher than a LUMO energy level of the third light emitting layer.

The LUMO energy level of the intermediate layer may be less than 1.5 electron volt (eV).

The intermediate layer may include a compound having at least one of a carbazole group and a triphenylamine group.

The first light emitting unit may include a first light emitting layer that may be to emit blue light, the second light emitting layer may be to emit red light, and the third light emitting layer may be to emit green light.

The first light emitting layer may include a blue fluorescent host and a blue fluorescent dopant.

The second light emitting layer may include a red hole transport host, a red electron transport host, and a red phosphorescent dopant, and the third light emitting layer may include a green hole transport host, a green electron transport host, and a green phosphorescent dopant.

The charge generation layer may include an n-type or kind charge generation layer adjacent to the first light emitting unit, and a p-type or kind charge generation layer adjacent to the second light emitting unit.

The light emitting element may further include a capping layer provided on the cathode electrode.

According to some embodiments, a light emitting element may include an anode electrode, a cathode electrode facing the anode electrode, and a light emitting structure provided between the anode electrode and the cathode electrode, and including a first light emitting unit, a charge generation layer, and a second light emitting unit. The second light emitting unit may include a second hole transport unit provided on the charge generation layer, a second electron transport unit facing the second hole transport unit and adjacent to the cathode electrode, and a second light emitting layer and a third light emitting layer provided between the second hole transport unit and the second electron transport unit. The second light emitting layer may include a red bipolar host and a red phosphorescent dopant.

The second light emitting layer may be provided between the second hole transport unit and the third light emitting layer, and the third light emitting layer may be provided between the second light emitting layer and the second electron transport unit.

The third light emitting layer may include a green hole transport host, a green electron transport host, and a green phosphorescent dopant.

An LUMO energy level of the red bipolar host may be higher than an LUMO energy level of the green electron transport host.

The LUMO energy level of the red bipolar host may be less than 1.9 eV.

The first light emitting unit may include a first hole transport unit provided on the anode electrode, a first electron transport unit facing the first hole transport unit and adjacent to the charge generation layer, and a first light emitting layer provided between the first hole transport unit and the first electron transport unit.

According to some embodiments, a display device may include the light emitting element.

The display device may include at least one selected from among a flat display, a curved display, a flexible display, a rollable display, a foldable display, a stretchable display, a head-up display, a head-mounted display, a wearable display, a micro display, a three-dimensional (3D) display, a virtual reality display, an augmented reality display, a mixed reality display, and one or more combinations thereof.

### BRIEF DESCRIPTION OF THE DRAWINGS

The preceding and other features of the disclosure will become more apparent by describing in further detail embodiments thereof with reference to the accompanying drawings, which are incorporated in and constitute a part of this specification. The drawings illustrate embodiments of the present disclosure and, together with the description, serve to explain principles of the present disclosure.

FIG. 1 is a diagram illustrating a display device according to some embodiments of the present disclosure.

FIG. 2 is a diagram illustrating a sub-pixel according to some embodiments of the present disclosure.

FIG. 3 is a diagram illustrating a display panel according to some embodiments of the present disclosure.

FIG. 4 is an exploded perspective view illustrating a portion of the display panel of FIG. 3.

FIG. 5 is a diagram illustrating some embodiments of any one of pixels of FIG. 4.

FIG. 6 is a diagram illustrating some embodiments of any one of the pixels of FIG. 4.

FIG. 7 is a plan view illustrating some embodiments of any one of the pixels of FIG. 4.

FIG. 8 is a cross-sectional view taken along a line I-I′ of FIG. 5.

FIG. 9 is a diagram illustrating a light emitting element according to some embodiments of the present disclosure.

FIG. 10 is a diagram illustrating a light emission principle of the light emitting element of FIG. 9.

FIG. 11 is a diagram illustrating a distribution of an exciton according to a position of the light emitting element of FIG. 9 for each grayscale level.

FIG. 12 is a diagram illustrating a light emitting element according to some embodiments of the present disclosure.

FIG. 13 is a diagram illustrating a light emission principle of the light emitting element of FIG. 12.

FIG. 14 is a diagram illustrating a distribution of an exciton according to a position of the light emitting element of FIG. 12 for each grayscale level.

FIG. 15 is a diagram illustrating a red light efficiency according to a current density for each light emitting element according to some embodiments of the present disclosure.

FIG. 16 is a diagram illustrating the current density according to a driving voltage for each light emitting element according to some embodiments of the present disclosure.

FIG. 17 is a diagram illustrating a light emitting element according to some embodiments of the present disclosure.

FIG. 18 is a diagram illustrating a light emission principle of the light emitting element of FIG. 17.

FIG. 19 is a diagram illustrating the distribution of the exciton according to a position of the light emitting element of FIG. 17 for each grayscale level.

FIG. 20 is a diagram illustrating the red light efficiency according to the current density for each light emitting element according to some embodiments of the present disclosure.

FIG. 21 is a diagram illustrating the current density according to a driving voltage for each light emitting element according to some embodiments of the present disclosure.

FIG. 22 is a diagram illustrating a display system according to some embodiments.

FIG. 23 is a diagram illustrating an application example of the display system of FIG. 22.

FIG. 24 is a diagram illustrating a head mounted display device worn by a user of FIG. 23.

### DETAILED DESCRIPTION

Hereinafter, a preferred embodiment according to the disclosure is described in more detail with reference to the accompanying drawings. It should be noted that in the following description, only portions necessary for understanding an operation according to the disclosure are described, and descriptions of other portions are omitted in order not to obscure the subject matter of the disclosure. In some embodiments, the disclosure may be embodied in other forms without being limited to the embodiment described herein. However, the embodiment described herein is provided to describe in more detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Like reference numerals refer to like elements throughout, and duplicative descriptions thereof may not be provided. In some embodiments, in the drawings, the thicknesses, ratios, and dimensions of elements are exaggerated for effective description of the technical contents. As utilized herein, the term “and/or” includes any and all combinations that the associated configurations can define.

Terms utilized herein are for describing specific embodiments and are not intended to limit the disclosure. Throughout the specification, in a case where a certain portion “includes”, the case refers to that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations. The terms of a singular form include plural forms unless otherwise specified. For example, “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well. It will be understood that the terms “include” “includes,” “including,” “comprise,” “comprises”, “comprising,” “has,” “having,” and/or “have”, when utilized in this specification, specify the presence of stated features, integers, steps, operations, elements, components and/or groups thereof, but do not preclude the presence or addition of one or more other features, integers, steps, operations, elements, components, and/or groups thereof.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component”, “component’-free”, and/or the like refers to that the “component” not being added, selected or utilized as a component in the composition, but the “component” of less than a suitable amount may still be included due to other impurities and/or external factor.

Here, terms such as first and second may be utilized to describe one or more suitable components, but these components are not limited to these terms. These terms are utilized to distinguish one component from another component. Therefore, a first component may refer to a second component within a range without departing from the scope disclosed herein.

Spatially relative terms such as “under”, “on”, and/or the like may be utilized for descriptive purposes, thereby describing a relationship between one element or feature and another element(s) or feature(s) as shown in the drawings. Spatially relative terms are intended to include other directions in utilize, in operation, and/or in manufacturing, in addition to the direction depicted in the drawings. For example, if (e.g., when) a device shown in the drawing is turned upside down, elements depicted as being positioned “under” other elements or features are positioned in a direction “on” the other elements or features. Therefore, in some embodiments, the term “under” may include both (e.g., simultaneously) directions of on and under. In some embodiments, the device may face in other directions (for example, rotated 90 degrees or in other directions) and thus the spatially relative terms utilized herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described herein, the shapes shown in the drawings may not show actual shapes of areas of a device, and the present embodiments are not limited thereto.

Hereinafter, embodiments of the disclosure will be described in more detail with reference to the accompanying drawings.

### Display Device

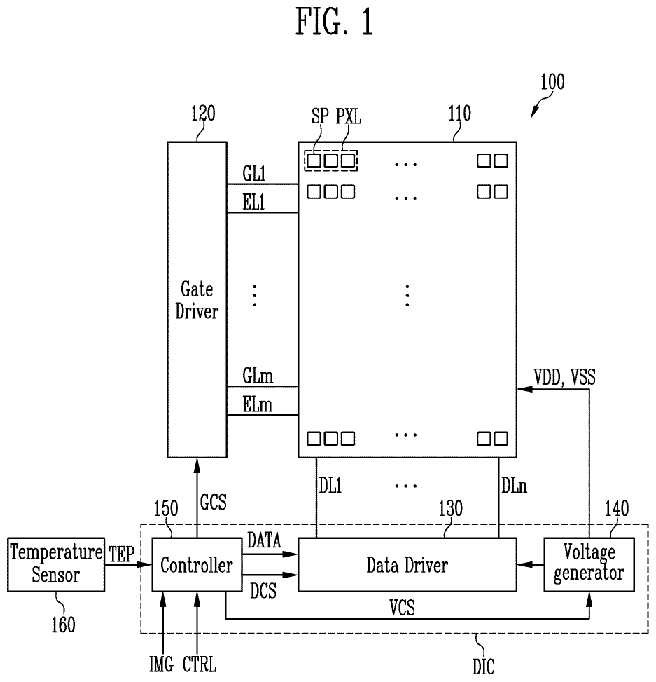

FIG. 1 is a diagram illustrating a display device according to some embodiments.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and/or the like.

In some embodiments, first to m-th emission control lines EL1 to ELm connected to the sub-pixels SP of the row direction may be further provided. In this case, the gate driver 120 may include an emission control driver configured to control the first to m-th emission control lines EL1 to ELm, and the emission control driver may operate under control of the controller 150.

The gate driver 120 may be provided on one side of the display panel 110. However, embodiments are not limited thereto. For example, the gate driver 120 may be divided into two or more physically and/or logically divided drivers, and such drivers may be provided on one side of the display panel 110 and another side of the display panel 110 opposite the one side. As described herein, the gate driver 120 may be provided around the display panel 110 in one or more suitable shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, and/or the like.

The data driver 130 may apply data signals having grayscale voltages corresponding to the image data DATA to the first to n-th data lines DL1 to DLn utilizing voltages from the voltage generator 140. If (e.g., when) the gate signal is applied to each of the first to m-th gate lines GL1 to GLm, the data signals corresponding to the image data DATA may be applied to the data lines DL1 to DLm. Accordingly, the corresponding sub-pixels SP may be to emit light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. In other embodiments, the first power voltage VDD or the second power voltage VSS may be provided by an external device of the display device 100.

In some embodiments, the voltage generator 140 may generate one or more suitable voltages. For example, the voltage generator 140 may generate an initialization voltage applied to the sub-pixels SP. For example, during a sensing operation for sensing electrical characteristics of transistors and/or light emitting elements of the sub-pixels SP, a set or predetermined reference voltage may be applied to the first to n-th data lines DL1 to DLn, and the voltage generator 140 may generate such a reference voltage.

The controller 150 controls overall operations of the display device 100. The controller 150 receives input image data and a control signal CTRL for controlling display of the image IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or display panel 110 and output image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a temperature near or around the temperature sensor 160 and generate temperature data TEP indicating the sensed temperature. In embodiments, the temperature sensor 160 may be provided adjacent to the display panel 110 and/or the driver integrated circuit DIC.

The controller 150 may control one or more suitable operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

In some embodiments, the display device 100 may include any one of a flat panel display, a curved display, a flexible display, a rollable display, a foldable display, a stretchable display, a head-up display, a head-mounted display, a wearable display, a micro display, a 3D display, a virtual reality display, an augmented reality display, and a mixed reality display.

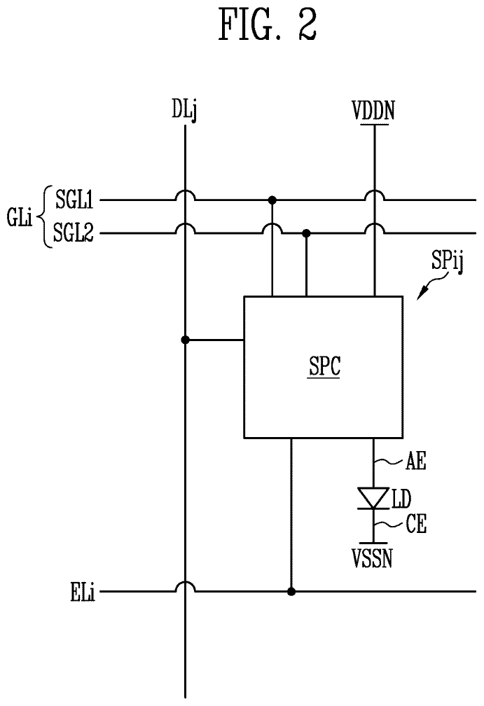

FIG. 2 is a diagram illustrating a sub-pixel according to some embodiments. In FIG. 2, a sub-pixel SPij arranged in an i-th (i is an integer greater than or equal to 1 and less than or equal to m) row and a j-th (j is an integer greater than or equal to 1 and less than or equal to n) column is shown as an example among the sub-pixels SP of FIG. 1.

Referring to FIG. 2, the sub-pixel SPij may include a sub-pixel circuit SPC and a light emitting element LD.

The light emitting element LD is connected between a first power voltage node VDDN and a second power voltage node VSSN. At this time, the first power voltage node VDDN is a node that transfers the first power voltage VDD of FIG. 1, and the second power voltage node VSSN is a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD according to signals received through such signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described herein, if (e.g., when) the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. If (e.g., when) the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light with a luminance corresponding to the data signal.

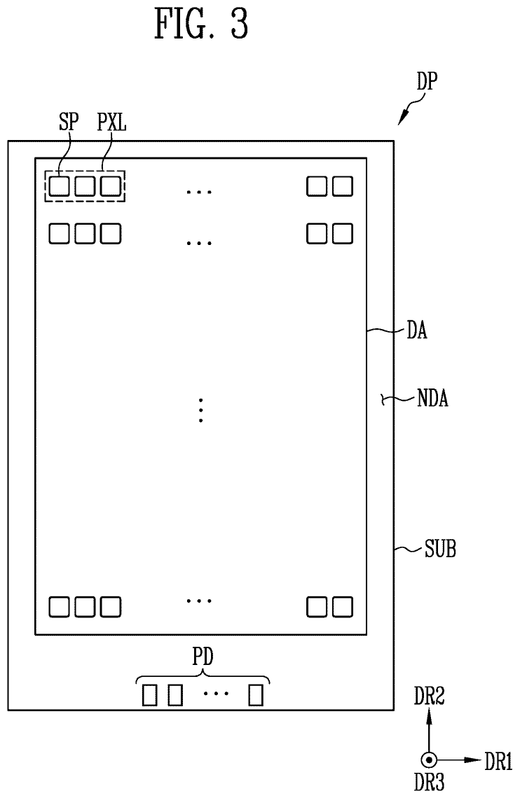

FIG. 3 is a diagram illustrating a display panel according to some embodiments.

Referring to FIG. 3, in some embodiments, the display panel 110 of FIG. 1 may be referenced as DP in FIG. 3 and may include a display area DA and a non-display area NDA. The display panel DP displays an image through the display area DA. The non-display area NDA is provided around the display area DA.

The display panel DP may include a substrate SUB, the sub-pixels SP, and pads PD.

If (e.g., when) the display panel DP is utilized as a display screen of a head mounted display (HMD) device, a virtual reality (VR) device, a mixed reality (MR) device, an augmented reality (AR) device, and/or the like, the display panel DP may be positioned very close to user's eyes. In this case, sub-pixels SP have a relatively high degree of integration. In order to increase a degree of integration of the sub-pixels SP, the substrate SUB may be (e.g., provided as) a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDoS) display device.

The sub-pixels SP are provided in the display area DA on the substrate SUB. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILET shape. The first direction DR1 may be a row direction, and the second direction DR2 may be a column direction.

Two or more sub-pixels among the plurality of sub-pixels SP may configure (e.g., to be) one pixel PXL.

A component for controlling the sub-pixels SP may be provided in the non-display area NDA on the substrate SUB. For example, lines connected to the sub-pixels SP, such as the first to m-th gate lines GL1 to GLm and the first to n-th data lines DL1 to DLn in FIG. 1, may be provided in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and may be provided in the non-display area NDA. In other embodiments, the gate driver 120 may be implemented as an integrated circuit separated from the display panel DP. In embodiments, the temperature sensor 160 may be provided in the non-display area NDA to sense a temperature of the display panel DP.

Pads PD are provided in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). In embodiments, voltages and signals necessary for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, if (e.g., when) the gate driver 120 is mounted on the display panel DP, the gate control signal GCS may be transmitted from the driver integrated circuit DIC to the gate driver 120 through the pads PD.

In embodiments, a circuit board may be electrically connected to the pads PD utilizing a conductive adhesive member such as an anisotropic conductive film. At this time, the circuit board may be a flexible circuit board (FPCB) or a flexible film having a flexible material. The driver integrated circuit DIC may be mounted on the circuit board to be electrically connected to the pads PD.

In embodiments, the display area DA may have one or more suitable shapes. The display area DA may have a closed loop shape including straight and/or curved sides. For example, the display area DA may have shapes such as a polygon, a circle, a semicircle, an ellipse, and/or the like.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials having a flexible property.

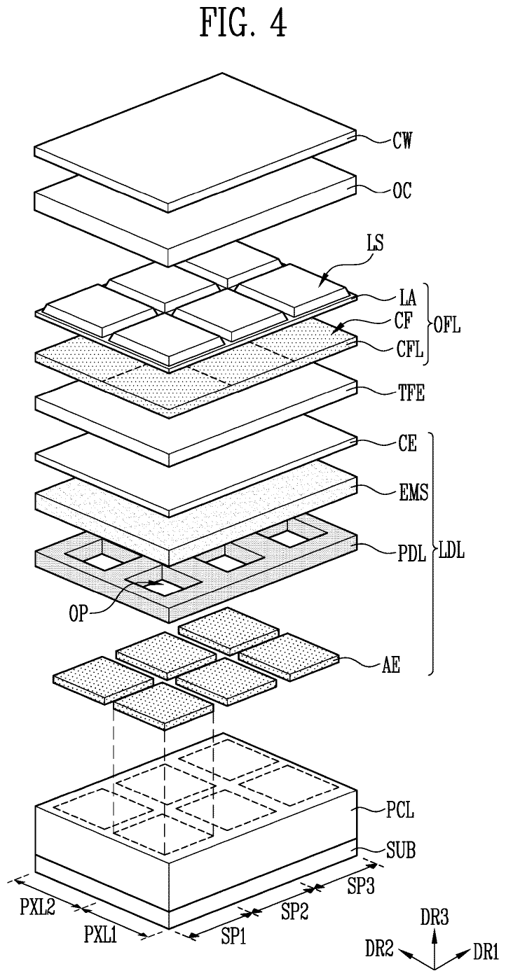

FIG. 4 is an exploded perspective view illustrating a portion of the display panel of FIG. 3. In FIG. 4, for clear and concise description, a portion of the display panel DP corresponding to two pixels PXL1 and PXL2 among the pixels PXL of FIG. 3 is schematically shown. A portion of the display panel DP corresponding to remaining pixels may be configured similarly.

Referring to FIGS. 3 and 4, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 4, the first to third sub-pixels SP1, SP2, and SP3 have quadrangle shapes if (e.g., when) viewed from a third direction DR3 crossing the first and second directions DR1 and DR2, and have sizes equal to each other. However, embodiments are not limited thereto. The first to third sub-pixels SP1, SP2, and SP3 may be modified to have one or more suitable shapes.

The display panel DP may include the substrate SUB, the pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed utilizing a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, and/or the like. In other embodiments, the substrate SUB may include a glass substrate. In still other embodiments, the substrate SUB may include a polyimide (PI) substrate.

The pixel circuit layer PCL is provided on the substrate SUB. The substrate SUB and/or the pixel circuit layer PCL may include insulating layers and conductive patterns provided between the insulating layers. The conductive patterns of the pixel circuit layer PCL may function as at least a portion of circuit elements, lines, and/or the like. The conductive patterns may include copper, but embodiments are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, if (e.g., when) the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, if (e.g., when) the substrate SUB is provided as a glass substrate or a PI substrate, the semiconductor portion and the gate electrode may be included in the pixel circuit layer PCL. Each capacitor may include electrodes spaced and/or apart from each other. For example, each capacitor may include electrodes overlapping each other on a plane defined by the first and second directions DR1 and DR2 (e.g., in a plan view), for example, each capacitor may include electrodes including a first electrode on a second electrodes. For example, each capacitor may include electrodes spaced and/or apart from each other in the third direction DR3 with an insulating layer interposed therebetween (e.g., between a first electrode and a second electrode of the electrodes of the capacitor).

The lines of the pixel circuit layer PCL may include signal lines connected to each of the first to third sub-pixels SP1, SP2, and SP3, for example, a gate line, an emission control line, a data line, and/or the like. The lines may further include a line connected to the first power voltage node VDDN of FIG. 2. In some embodiments, the lines may further include a line connected to the second power voltage node VSSN of FIG. 2.

The light emitting element layer LDL may include the anode electrodes (or referred to as anode) AE, a pixel defining layer PDL, the light emitting structure EMS, and the cathode electrode (or referred to as cathode) CE.

The anode electrodes AE may be provided on the pixel circuit layer PCL. The anode electrodes AE may contact the circuit elements of the pixel circuit layer PCL. The anode electrodes AE may include an opaque conductive material capable of reflecting light, but embodiments are not limited thereto.

The pixel defining layer PDL is provided on the anode electrodes AE. The pixel defining layer PDL may include an opening OP exposing a portion of each of the anode electrodes AE. The opening OP of the pixel defining layer PDL may be understood as emission areas corresponding to the first to third sub-pixels SP1 to SP3, respectively.

In embodiments, the pixel defining layer PDL may include an inorganic material. In this case, the pixel defining layer PDL may include a plurality of stacked inorganic layers. For example, the pixel defining layer PDL may include silicon oxide SiOₓ (e.g., x may be 2 or less) and silicon nitride SiNₓ, (e.g., x may be 1 or less). In other embodiments, the pixel defining layer PDL may include an organic material. However, a material of the pixel defining layer PDL is not limited thereto.

The light emitting structure EMS may be provided on the anode electrodes AE exposed by the opening OP of the pixel defining layer PDL. The light emitting structure EMS may include a light emitting layer configured to emit light, an electron transport layer configured to transport an electron, a hole transport layer configured to transport a hole, and/or the like.

In embodiments, the light emitting structure EMS may fill the opening OP of the pixel defining layer PDL, and may be entirely provided on the pixel defining layer PDL. In other words, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and each of them may be provided in the opening OP of the pixel defining layer PDL.

The cathode electrode CE may be provided on the light emitting structure EMS. The cathode electrode CE may extend across the first to third sub-pixels SP1 to SP3. As described herein, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. In embodiments, the cathode electrode CE may include at least one of one or more suitable transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and a mixture thereof. However, a material of the cathode electrode CE is not limited thereto.

It may be understood that any one of the anode electrodes AE, a portion of the light emitting structure EMS overlapping it, and a portion of the cathode electrode CE overlapping it configure one light emitting element LD (refer to FIG. 2). In other words, each of the light emitting elements of the first to third sub-pixels SP1 to SP3 may include one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and if (e.g., when) the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE is provided on the cathode electrode CE. The encapsulation layer TFE may cover the light emitting element layer LDL and/or the pixel circuit layer PCL. The encapsulation layer TFE may be configured to prevent or reduce oxygen, moisture, and/or the like from passing through into the light emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOₓN_{y}), and/or the like. For example, the organic layer may include an organic insulating material such as acrylic resin (polyacrylates resin), epoxy resin, phenolic resin, polyamides resin, polyimides resin, unsaturated polyester resin, polyphenylenethers resin, polyphenylenesulfides resin, or benzocyclobutene (BCB). However, materials of the organic and the inorganic layers of the encapsulation layer TFE are not limited thereto.

In order to improve an encapsulation efficiency of the encapsulation layer TFE, the encapsulation layer TFE may further include a thin film including aluminum oxide (AlOₓ, e.g., x may be 1.5 or less). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments are not limited thereto. The encapsulation layer TFE may further include a thin film formed of at least one of one or more suitable materials suitable for improving the encapsulation efficiency.

The optical functional layer OFL is provided on the encapsulation layer TFE. The optical functional layer OFL may include a color filter layer CFL and a lens array LA.

The color filter layer CFL is provided between the encapsulation layer TFE and the lens array LA. The color filter layer CFL is configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red light, the color filter corresponding to the second sub-pixel SP2 may pass green light, and the color filter corresponding to the third sub-pixel SP3 may pass blue light. According to the light emitted from the light emitting structure EMS of each sub-pixel, at least a portion of the color filters CF may not be provided.

The lens array LA is provided on the color filter layer CFL. The lens array LA may include lenses LS respectively corresponding to the first to third sub-pixels SP1 to SP3. Each of the lenses LS may improve light output efficiency by outputting the light emitted from the light emitting structure EMS to an intended path. The lens array LA may have a relatively high refractive index. For example, the lens array LA may have a refractive index higher than that of the overcoat layer OC. In embodiments, the lenses LS may include an organic material. In embodiments, the lenses LS may include an acrylate material. However, a material of the lenses LS is not limited thereto.

In embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. For example, in a central area of the display area DA (see FIG. 3), a center of the color filter CF and a center of the lens LS may be aligned with or overlap with a center of the opening OP of the corresponding pixel definition layer PDL if (e.g., when) viewed in the third direction DR3. For example, in the central area of the display area DA, the opening OP of the pixel defining layer PDL may completely overlap the corresponding color filter CF of the color filter layer CFL and the corresponding lens LS of the lens array LA. In an area adjacent to the non-display area NDA in the display area DA, the center of the color filter CF and the center of the lens LS may be shifted in a plane direction from the center of the opening OP of the corresponding pixel defining layer PDL if (e.g., when) viewed in the third direction DR3. For example, in the area adjacent to the non-display area NDA in the display area DA, the opening OP of the pixel defining layer PDL may be partially overlapped with the corresponding color filter CF of the color filter layer CFL and the corresponding lens LS of the lens array LA. Accordingly, at a center of the display area DA, the light emitted from the light emitting structure EMS may be efficiently output in a normal direction of a display surface. At an area adjacent to the non-display area NDA in the display area DA, the light emitted from the light emitting structure EMS may be efficiently output in a direction inclined by a set or predetermined angle with respect to the normal direction of the display surface.

The overcoat layer OC may be provided on the lens array LA. The overcoat layer OC may cover the optical functional layer OFL, the encapsulation layer TFE, the light emitting structure EMS, and/or the pixel circuit layer PCL. The overcoat layer OC may include one or more suitable materials suitable for protecting layers thereunder from a foreign substance such as dust or moisture. For example, the overcoat layer OC may include at least one of an inorganic insulating layer and an organic insulating layer. For example, the overcoat layer OC may include epoxy resin, but embodiments are not limited thereto. The overcoat layer OC may have a refractive index lower than that of the lens array LA.

The cover window CW may be provided on the overcoat layer OC. The cover window CW is configured to protect layers thereunder. The cover window CW may have a refractive index higher than that of the overcoat layer OC. The cover window CW may include glass, but embodiments are not limited thereto. For example, the cover window CW may be an encapsulation glass configured to protect components provided thereunder. In other embodiments, the cover window CW may not be provided.

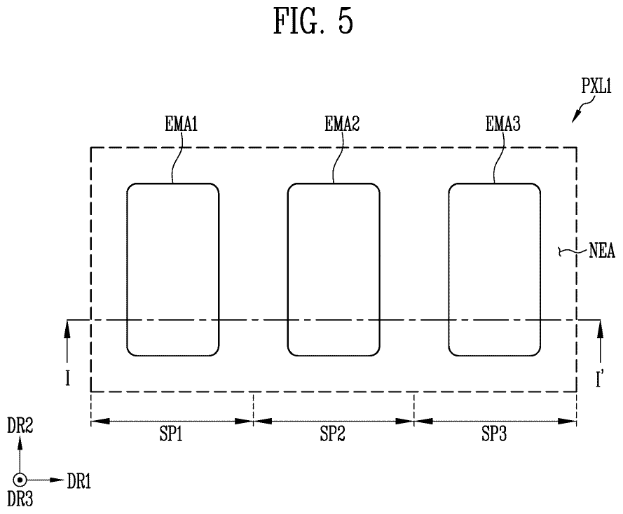

FIG. 5 is a diagram illustrating some embodiments of any one of the pixels of FIG. 4. In FIG. 5, the first pixel PXL1 among the first and second pixels PXL1 and PXL2 of FIG. 4 is schematically shown for clear and concise description. The remaining pixels may be configured similarly to the first pixel PXL1.

Referring to FIGS. 4 and 5, the first pixel PXL1 may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the light emitting structure EMS (refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described with reference to FIG. 4, each emission area may be understood as the opening OP of the pixel defining layer PDL corresponding to each of the first to third sub-pixels SP1 to SP3.

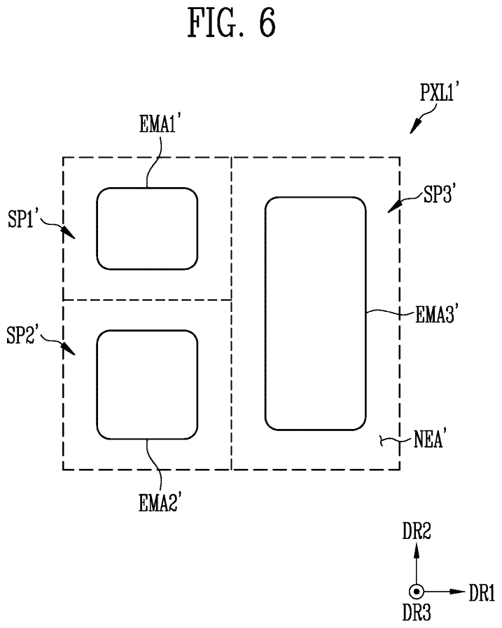

FIG. 6 is a diagram illustrating some embodiments of any one of the pixels of FIG. 4.

Referring to FIG. 6, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have the area greater than that of the first sub-pixel SP1′, and the third sub-pixel SP3′ may the area greater than that of the second sub-pixel SP2′. Accordingly, the second emission area EMA2′ may have the area greater than that of the first emission area EMA1′, and the third emission area EMA3′ may the area greater than that of the second emission area EMA2′. However, embodiments are not limited thereto. For example, the first and second sub-pixels SP1′ and SP2′ may have substantially the same area, and the third sub-pixel SP3′ may have the area greater than that of each of the first and second sub-pixels SP1′ and SP2′. As described herein, the areas of the first to third sub-pixels SP1′ to SP3′ may be variously modified according to embodiments.

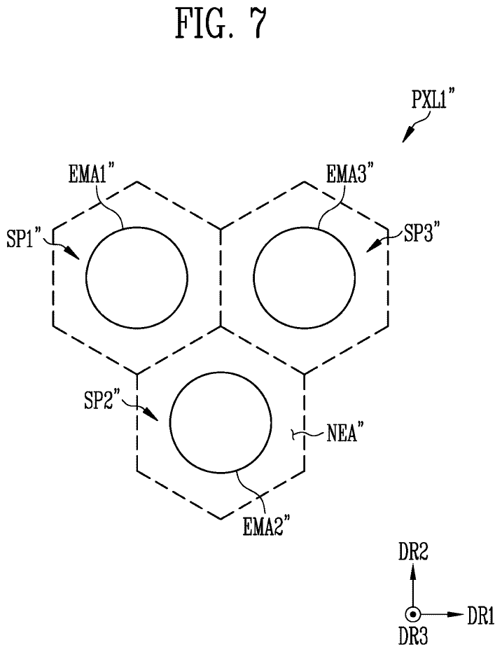

FIG. 7 is a plan view illustrating some embodiments of any one of the pixels of FIG. 4.

Referring to FIG. 7, a first pixel PXL1″ may include first to third sub-pixels SP1″ to SP3″.

The first sub-pixel SP1″ may include a first emission area EMA1″ and a non-emission area NEA″ around the first emission area EMA1″. The second sub-pixel SP2″ may include a second emission area EMA2″ and a non-emission area NEA″ around the second emission area EMA2″. The third sub-pixel SP3″ may include a third emission area EMA3″ and a non-emission area NEA″ around the third emission area EMA3″.

The first to third sub-pixels SP1″ to SP3″ may have polygonal shapes if (e.g., when) viewed in the third direction DR3 (e.g., in a plan view). For example, shapes of the first to third sub-pixels SP1″ to SP3″ may be hexagonal shapes as shown in FIG. 7.

The first to third emission areas EMA1″ to EMA3″ may have circular shapes if (e.g., when) viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be provided in a direction inclined by an acute angle (or a diagonal direction) based on the second direction DR2 with respect to the first sub-pixel SP1″.

An arrangement of the sub-pixels shown in FIGS. 5 to 7 is merely an example, and embodiments are not limited thereto. For example, each pixel may include two or more sub-pixels, the sub-pixels may be arranged in one or more suitable methods, each of the sub-pixels may have one or more suitable shapes, and each of emission areas of each of the sub-pixels may also have one or more suitable shapes.

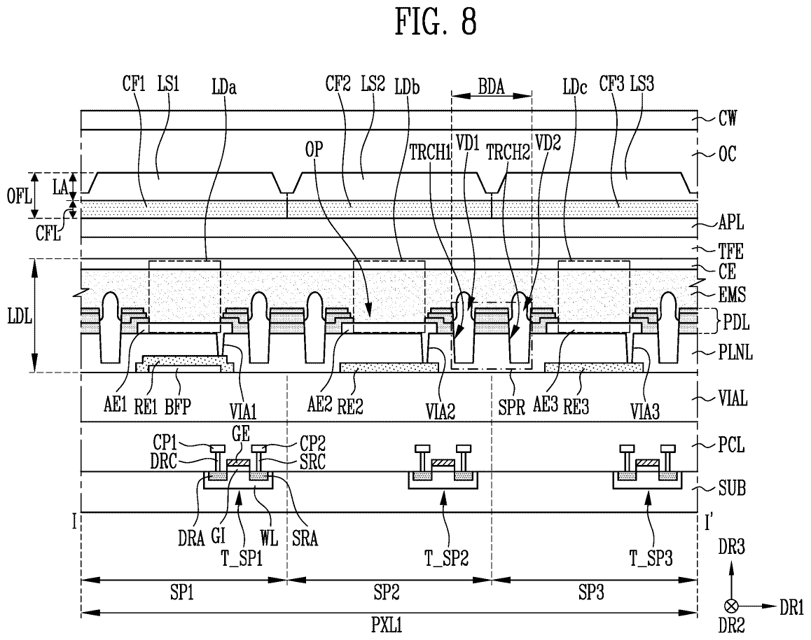

FIG. 8 is a cross-sectional view taken along a line I-I′ of FIG. 5.

Referring to FIG. 8, the substrate SUB and the pixel circuit layer PCL provided on the substrate SUB are provided.

The substrate SUB may include a silicon wafer substrate formed utilizing a semiconductor process. For example, the substrate SUB may include silicon, germanium, and/or silicon-germanium.

The pixel circuit layer PCL is provided on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1, the transistor T_SP2 of the second sub-pixel SP2 may be any one of the transistors included in the sub-pixel circuit SPC of the second sub-pixel SP2, and the transistor T_SP3 of the third sub-pixel SP3 may be any one of the transistors included in the sub-pixel circuit SPC of the third sub-pixel SP3. In FIG. 8, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be provided in the substrate SUB. A well WL formed through an ion injection process may be provided in the substrate SUB, and the source area SRA and the drain area DRA may be provided to be spaced and/or apart from each other in the well WL. An area between the source area SRA and the drain area DRA in the well WL may be defined as a channel area.

The gate electrode GE may overlap the channel area between the source area SRA and the drain area DRA and may be provided in the pixel circuit layer PCL. The gate electrode GE may be spaced and/or apart from the well WL or the channel area by an insulating material such as a gate insulating layer GI. The gate electrode GE may include a conductive material.

A plurality of layers included in the pixel circuit layer PCL may include insulating layers and conductive patterns provided between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described herein, the substrate SUB and the pixel circuit layer PCL may include the circuit elements of each of the first to third sub-pixels SP1 to SP3.

A via layer VIAL is provided on the pixel circuit layer PCL. The via layer VIAL may cover the pixel circuit layer PCL and may have a generally flat surface. The via layer VIAL is configured to planarize step differences on the pixel circuit layer PCL. The via layer VIAL may include at least one of silicon oxide (SiOₓ, e.g., x may be 2 or less and 0 or more), silicon nitride (SiNₓ, e.g., x may be 1 or less and 0 or more), and silicon carbon nitride (SiCN), but embodiments are not limited thereto.

The light emitting element layer LDL is provided on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are provided in the first to third sub-pixels SP1 to SP3, respectively. Each of the first to third reflective electrodes RE1 to RE3 may contact the circuit element provided in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them, but embodiments are not limited thereto.

In embodiments, a connection electrode may be provided under each of the first to third reflective electrodes RE1 to RE3. The connection electrode may improve an electrical connection characteristic between the corresponding reflective electrode and the circuit elements of the pixel circuit layer PCL. The connection electrode may have a multiple layer structure. The multiple layer structure may include titanium (Ti), titanium nitride (TiN), tantalum nitride (TaN), and/or the like, but embodiments are not limited thereto. In embodiments, a corresponding reflective electrode may be positioned between multiple layers of the connection electrode.

A buffer pattern BFP may be provided under at least one of the first to third reflective electrodes RE1 to RE3. The buffer pattern BFP may include an inorganic material such as silicon carbon nitride, but embodiments are not limited thereto. By disposing the buffer pattern BFP, a height of the third direction DR3 of the corresponding reflective electrode may be adjusted. For example, the buffer pattern BFP may be provided between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. Light emitted from the light emitting layer of the light emitting structure EMS may be at least partially amplified by reciprocating between the corresponding reflective electrode and the cathode electrode CE, and the amplified light may be output through the cathode electrode CE. As described herein, a distance between each reflective electrode and the cathode electrode CE may be understood as a resonance distance for the light emitted from the light emitting layer of the light emitting structure EMS.

The first sub-pixel SP1 may have a resonance distance shorter than that of other sub-pixels due to the buffer pattern BFP. The resonance distance adjusted as described herein may allow light of a specific wavelength range (for example, red) to be effectively and efficiently amplified. Accordingly, the first sub-pixel SP1 may effectively and efficiently output light of a corresponding wavelength range.

In FIG. 8, the buffer pattern BFP is provided to the first sub-pixel SP1 and is not provided to the second and third sub-pixels SP2 and SP3, but embodiments are not limited thereto. The buffer pattern BFP may also be provided to at least one of the second and third sub-pixels SP2 and SP3 to adjust a resonance distance of at least one of the second and third sub-pixels SP2 and SP3. For example, the first to third sub-pixels SP1 to SP3 may correspond to red, green, and blue, respectively, and according to the needs, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize step differences between the first to third reflective electrodes RE1 to RE3, a planarization layer PLNL may be provided on the via layer VIAL and the first to third reflective electrodes RE1 to RE3. The planarization layer PLNL may generally cover the first to third reflective electrodes RE1 to RE3 and the via layer VIAL, and may have a flat surface. In embodiments, the planarization layer PLNL may not be provided.

On the planarization layer PLNL, the first to third anode electrodes AE1 to AE3 respectively overlapping the first to third reflective electrodes RE1 to RE3 are provided. The first to third anode electrodes AE1 to AE3 may have shapes similar to the first to third emission areas EMA1 to EMA3 of FIG. 5 if (e.g., when) viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

In embodiments, the first to third anode electrodes AE1 to AE3 may include at least one of transparent conductive materials such as indium tin oxide (ITO), indium zinc oxide (IZO), zinc oxide (ZnO), indium gallium zinc oxide (IGZO), and indium tin zinc oxide (ITZO). However, a material of the first to third anode electrodes AE1 to AE3 are not limited thereto. For example, the first to third anode electrodes AE1 to AE3 may include titanium nitride.

In embodiments, insulating layers for adjusting a height of one or more of the first to third anode electrodes AE1 to AE3 may be further provided. The insulating layers may be provided between one or more of the first to third anode electrodes AE1 to AE3 and the corresponding reflective electrodes. In this case, the planarization layer PLNL and/or the buffer pattern BFP may not be provided. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE.

The pixel defining layer PDL is provided on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define the emission area of each of the first to third sub-pixels SP1 to SP3. As described herein, the pixel defining layer PDL may be provided in the non-emission area NEA of FIG. 5 and may define the first to third emission areas EMA1 to EMA3 of FIG. 5.

In embodiments, the pixel defining layer PDL may include a plurality of inorganic insulating layers. Each of the plurality of inorganic insulating layers may include at least one of silicon oxide (SiOₓ, e.g., x may be 2 or less and 0 or more) and silicon nitride (SiNₓ, e.g., x may be 1 or less and 0 or more). For example, the pixel defining layer PDL may include first to third inorganic insulating layers sequentially stacked, and the first to third inorganic insulating layers may include silicon nitride, silicon oxide, and silicon nitride, respectively. However, embodiments are not limited thereto. The first to third inorganic insulating layers may have a cross-section of a step shape in an area adjacent to the opening OP.

A separator SPR may be provided in a boundary area BDA between neighboring sub-pixels. In other words, the separator SPR may be provided in each of the boundary areas between the sub-pixels SP of FIG. 3.

The separator SPR may cause to have a discontinuity in the light emitting structure EMS at the boundary area BDA. For example, the light emitting structure EMS may be disconnected or bent at the boundary area BDA by the separator SPR.

The separator SPR may be provided in or on the pixel defining layer PDL. The pixel defining layer PDL may include one or more trenches TRCH1 and TRCH2 as the separator SPR in the boundary area BDA. In embodiments, as shown in FIG. 8, one or more trenches TRCH1 and TRCH2 may pass through the pixel defining layer PDL and may partially pass through the planarization layer PLNL. In other embodiments, one or more trenches TRCH1 and TRCH2 may pass through the pixel defining layer PDL and the planarization layer PLNL, and may partially pass through the via layer VIAL. In other embodiments, one or more trenches TRCH1 and TRCH2 may at least partially pass through the planarization layer PLNL and/or via layer VIAL, and a portion of the pixel defining layer PDL may be provided in one or more trenches TRCH1 and TRCH2.

In FIG. 8, two trenches TRCH1 and TRCH2 are provided to the boundary area BDA. However, embodiments are not limited thereto. For example, the pixel defining layer PDL may include one trench in the boundary area BDA. In some embodiments, the pixel defining layer PDL may include three or more trenches in the boundary area BDA.

Due to the first and second trenches TRCH1 and TRCH2, in the boundary area BDA, discontinuous portions such as a first void VD1 and a second void VD2 may be formed in the light emitting structure EMS. A portion of a plurality of layers stacked in the light emitting structure EMS may be disconnected or bent by the first and second voids VD1 and VD2. For example, at least one charge generation layer included in the light emitting structure EMS may be disconnected in the first and second voids VD1 and VD2. As described herein, portions of the light emitting structure EMS included in the first to third sub-pixels SP1 to SP3 may be at least partially separated due to the first and second trenches TRCH1 and TRCH2.

In FIG. 8, in the boundary area BDA, the first and second voids VD1 and VD2 are formed in the light emitting structure EMS, but this is example, and embodiments are not limited thereto. For example, in the boundary area BDA, a valley of a concave shape may be formed in the light emitting structure EMS. According to shapes of the first and second trenches TRCH1 and TRCH2, discontinuous portions formed in the light emitting structure EMS may be variously changed.

In embodiments, the light emitting structure EMS may be formed through a process of vacuum deposition, inkjet printing, and/or the like. In this case, the same materials as the light emitting structure EMS may be positioned on bottom surfaces of the first and second trenches TRCH1 and TRCH2 adjacent to the via layer VIAL.

The separator SPR may be variously modified and provided so that the light emitting structure EMS may have a discontinuous portion in the boundary area BDA. In embodiments, inorganic insulating patterns additionally stacked on the pixel defining layer PDL may be provided in the boundary area BDA without the first and second trenches TRCH1 and TRCH2. Among the additionally stacked inorganic insulating patterns, a width of an uppermost inorganic insulating pattern may be greater than a width of an inorganic insulating pattern provided immediately thereunder. For example, in the boundary area BDA, first to third inorganic insulating patterns may be sequentially stacked from the pixel defining layer PDL, and the uppermost third inorganic insulating pattern may have a width greater than that of the second inorganic insulating pattern. For example, the pixel defining layer PDL may have a cross-section of a “T” shape or an “I” shape in the boundary area BDA. According to the shape of the pixel defining layer PDL, the plurality of layers included in the light emitting structure EMS may be at least partially disconnected or bent in the boundary area BDA.

The light emitting structure EMS may be provided on the anode electrodes AE exposed by the opening OP of the pixel defining layer PDL. The light emitting structure EMS may fill the opening OP of the pixel defining layer PDL and may be provided entirely across the first to third sub-pixels SP1 to SP3. As described herein, the light emitting structure EMS may be at least partially disconnected or bent in the boundary area BDA by the separator SPR. Accordingly, during an operation of the display panel DP, a current flowing out from each of the first to third sub-pixels SP1 to SP3 to a neighboring sub-pixel through the layers included in the light emitting layer may be reduced. Therefore, first to third light emitting elements LDa to LDc may operate with relatively high reliability.

The cathode electrode CE may be provided on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping the first anode electrode AE1, and a portion of the cathode electrode CE overlapping the first anode electrode AE1 may configure the first light emitting element LDa. The second anode electrode AE2, a portion of the light emitting structure EMS overlapping the second anode electrode AE2, and a portion of the cathode electrode CE overlapping the second anode electrode AE2 may configure the second light emitting element LDb. The third anode electrode AE3, a portion of the light emitting structure EMS overlapping the third anode electrode AE3, and a portion of the cathode electrode CE overlapping the third anode electrode AE3 may configure the third light emitting element LDc.

The encapsulation layer TFE is provided on the cathode electrode CE. The encapsulation layer TFE may prevent or reduce oxygen, moisture, and/or the like from penetrating into the light emitting element layer LDL.

The optical functional layer OFL is provided on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

In embodiments, the first to third color filters CF1 to CF3 may partially overlap in the boundary area BDA. In other embodiments, the first to third color filters CF1 to CF3 may be spaced and/or apart from each other, and a black matrix may be provided between the first to third color filters CF1 to CF3.

The lens array LA is provided on the color filter layer CFL. The lens array LA may include first to third lenses LS1 to LS3 respectively corresponding to the first to third sub-pixels SP1 to SP3. Each of the first to third lenses LS1 to LS3 may improve light output efficiency by outputting light emitted from the first to third light emitting elements LDa to LDc to an intended path.

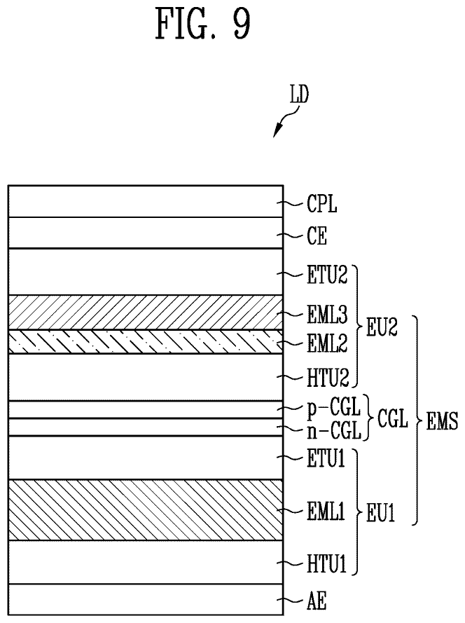

FIG. 9 is a diagram illustrating a light emitting element according to some embodiments.

Referring to FIG. 9, the light emitting element LD may have a tandem structure in which a first light emitting unit EU1 and a second light emitting unit EU2 are stacked. In this case, each of the first to third light emitting elements LDa to LDc in FIG. 8 may be configured as the light emitting element LD. The light emitting element LD may include the anode electrode AE, the light emitting structure EMS, and the cathode electrode CE. According to some embodiments, the light emitting element LD may further include a capping layer CPL.

The light emitting structure EMS may be provided between the anode electrode AE and the cathode electrode CE. The light emitting structure EMS may include the first light emitting unit EU1, a charge generation layer CGL, and the second light emitting unit EU2. Each of the first and second light emitting units EU1 and EU2 may be to emit light according to an applied current. The charge generating layer CGL may provide an electron or a hole.

In embodiments, the first light emitting unit EU1 and the second light emitting unit EU2 may be to emit light of different colors. Accordingly, the light emitted from each of the first light emitting unit EU1 and the second light emitting unit EU2 may be mixed and viewed as white light. For example, the first light emitting unit EU1 may be to emit blue light, and the second light emitting unit EU2 may be to emit yellow light.

The first light emitting unit EU1 may be provided between the anode electrode AE and the charge generation layer CGL. The first light emitting unit EU1 may include a first hole transport unit HTU1, a first light emitting layer EML1, and a first electron transport unit ETU1. The first light emitting unit EU1 may be to emit light based on a hole from the anode electrode AE and an electron from the charge generation layer CGL.

The first hole transport unit HTU1 may be provided between the anode electrode AE and the first light emitting layer EML1. The first hole transport unit HTU1 may include at least one of a hole injection layer and a hole transport layer, and may further include a hole buffer layer, an electron blocking layer, and/or the like if (e.g., when) necessary. The first hole transport unit HTU1 may transport the hole from the anode electrode AE to the first light emitting layer EML1.

The first light emitting layer EML1 may be provided between the first hole transport unit HTU1 and the first electron transport unit ETU1. In embodiments, the first light emitting layer EML1 may be to emit blue light. In embodiments, the first light emitting layer EML1 may include a blue fluorescent host and a blue fluorescent dopant, but is not limited thereto. For example, the first light emitting layer EML1 may include a blue phosphorescent host and a blue phosphorescent dopant.

The first electron transport unit ETU1 may be provided between the charge generation layer CGL and the first light emitting layer EML1. The first electron transport unit ETU1 may include at least one of an electron injection layer and an electron transport layer, and may further include an electron buffer layer, a hole blocking layer, and/or the like if (e.g., when) necessary. The first electron transport unit ETU1 may transport the electron from the charge generation layer CGL to the first light emitting layer EML1.

The charge generation layer CGL may be provided between the first light emitting unit EU1 and the second light emitting unit EU2. The charge generation layer CGL may include organic layers. In embodiments, the charge generation layer CGL may include a p-type or kind charge (e.g., p-charge) generation layer p-CGL and an n-type or kind charge (e.g., n-charge) generation layer n-CGL. The p-type or kind charge generation layer p-CGL may be adjacent to the second light emitting unit EU2 (or the second hole transport unit HTU2). The p-type or kind charge generation layer p-CGL may provide the hole to the second light emitting unit EU2. For example, the p-type or kind charge generation layer p-CGL may include a p-type or kind dopant such as HAT-CN, TCNQ, or NDP-9, but is not limited thereto. The n-type or kind charge generation layer n-CGL may be adjacent to the first light emitting unit EU1 (or the first electron transport unit ETU1). The n-type or kind charge generation layer n-CGL may provide the electron to the first light emitting unit EU1. For example, the n-type or kind charge generation layer n-CGL may include an alkali metal, an alkaline earth metal, a lanthanide-based metal, or a combination thereof, but is not limited thereto.

The second light emitting unit EU2 may be provided between the cathode electrode CE and the charge generation layer CGL. The second light emitting unit EU2 may include a second hole transport unit HTU2, a second light emitting layer EML2, a third light emitting layer EML3, and a second electron transport unit ETU2. The second light emitting unit EU2 may be to emit light based on the electron from the cathode electrode CE and the hole from the charge generation layer CGL.

The second hole transport unit HTU2 may be provided between the charge generation layer CGL (or the p-type or kind charge generation layer p-CGL) and the second light emitting layer EML2. The second hole transport unit HTU2 may include at least one of a hole injection layer and a hole transport layer, and may further include a hole buffer layer, an electron blocking layer, and/or the like if (e.g., when) necessary. The second hole transport unit HTU2 may transport the hole from the p-type or kind charge generation layer p-CGL to the second light emitting layer EML2 and the third light emitting layer EML3.

The second light emitting layer EML2 may be provided between the second hole transport unit HTU2 and the third light emitting layer EML3. In embodiments, the second light emitting layer EML2 may be to emit red light. In embodiments, the second light emitting layer EML2 may include a red hole transport host, a red electron transport host, and a red phosphorescent dopant. The red hole transport host may be a compound with a strong hole characteristic and may include a moiety (or a hole transport moiety) that easily accepts the hole. For example, the hole transport moiety may include an amine group, carbazole group, dibenzofuran group, dibenzothiophene group, fluorene group, and/or the like, but is not limited thereto. The red electron transport host may be a compound with a strong electron characteristic and may include a moiety (or an electron transport moiety) that easily accepts the electron. For example, the electron transport moiety may include —F, a cyano group, a C₁-C₆₀ alkyl group substituted with —F or a cyano group, a C₆-C₆₀ aryl group substituted with —F or a cyano group, a π-electron deficient nitrogen-containing cyclic group, and/or the like, but is not limited to. The red hole transport host and the red electron transport host may be mixed in a weight ratio that hole transport and electron transport are balanced.

The third light emitting layer EML3 may be provided between the second light emitting layer EML2 and the second electron transport unit ETU2. In embodiments, the third light emitting layer EML3 may be to emit green light. In embodiments, the third light emitting layer EML3 may include a green hole transport host, a green electron transport host, and a green phosphorescent dopant. The green hole transport host may be a compound with a strong hole characteristic and may include a hole transport moiety. The green hole transport host may be configured of a compound equal to or different from that of the red hole transport host. The green electron transport host may be a compound with a strong electron characteristic and may include an electron transport moiety. The green electron transport host may be configured of a compound equal to or different from that of the red electron transport host. A mixture ratio of the green hole transport host and the green electron transport host is not particularly limited, and the green hole transport host and the green electron transport host may be mixed in a weight ratio that hole transport and electron transport are balanced.

As the second light emitting unit EU2 includes the second light emitting layer EML2 and the third light emitting layer EML3, the red light emitted from the second light emitting layer EML2 and the green light emitted from the third light emitting layer EML3 may be mixed to provide yellow light.

The second electron transport unit ETU2 may be provided between the third light emitting layer EML3 and the cathode electrode CE. The second electron transport unit ETU2 may include at least one of an electron injection layer and an electron transport layer, and may further include an electron buffer layer, a hole blocking layer, and/or the like if (e.g., when) necessary. The second electron transport unit ETU2 may transport the electron from the cathode electrode CE to the second light emitting layer EML2 and the third light emitting layer EML3.

The capping layer CPL may be provided in a direction in which light is emitted. For example, the capping layer CPL may be provided on the cathode electrode CE. The capping layer CPL may improve external light emission efficiency based on a principle of constructive interference. The capping layer CPL may include an organic material, an inorganic material, or a composite material including an organic material and an inorganic material.

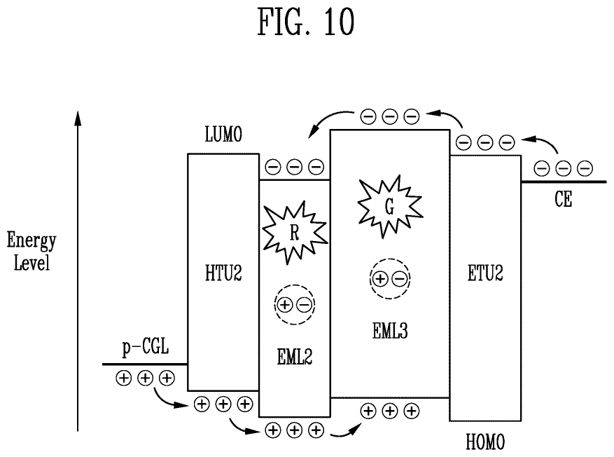

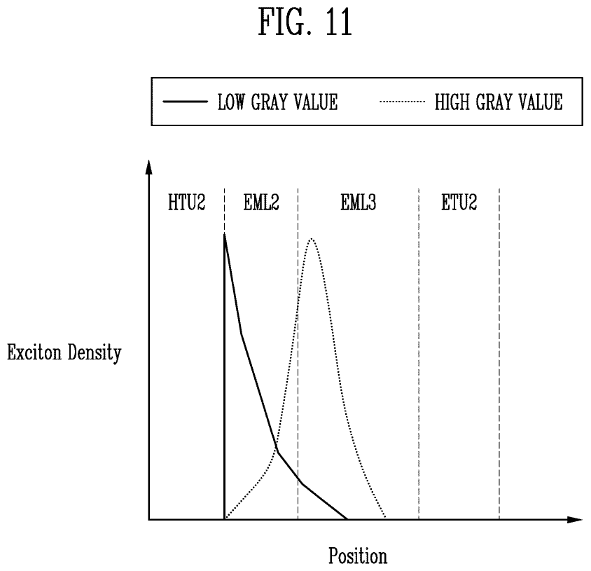

FIG. 10 is a diagram illustrating a light emission principle of the light emitting element of FIG. 9. In FIG. 10, components related to light emission of the second light emitting layer EML2 and the third light emitting layer EML3 are shown, and remaining components are omitted. FIG. 11 is a diagram illustrating a distribution of an exciton according to a position of the light emitting element of FIG. 9 for each grayscale level (e.g., each gray level).

Referring to FIGS. 9 and 10, if (e.g., when) a voltage is applied to the light emitting element LD (see FIG. 9), a hole moves along a highest occupied molecular orbital (HOMO) energy level. For example, the hole from the p-type or kind charge generation layer p-CGL reach the second light emitting layer EML2 and the third light emitting layer EML3 through the second hole transport unit HTU2. In some embodiments, the electron moves along a lowest unoccupied molecular orbital (LUMO) energy level. For example, the electron from the cathode electrode CE reaches the second light emitting layer EML2 and the third light emitting layer EML3 through the second electron transport unit ETU2. Accordingly, the exciton obtained by recombining the hole and the electron are formed in each of the second light emitting layer EML2 and the third light emitting layer EML3, and the second light emitting layer EML2 emits red light (R) and the third light emitting layer EML3 emits green light (G).

At this time, because the LUMO energy level of the second light emitting layer EML2 is lower (or deeper) than the LUMO energy level of the third light emitting layer EML3, the electron is easily and quickly injected from the third light emitting layer EML3 to the second light emitting layer EML2. In particular, as an excessive electron is injected into the second light emitting layer EML2 at a relatively low grayscale level, a red light efficiency is excessively increased. As a result, a roll-off phenomenon in which the red light efficiency rapidly decreases at a relatively high grayscale level may occur due to saturation, a characteristic deterioration, and/or the like of the second light emitting layer EML2.

Referring to FIG. 11, because the electron injection from the third light emitting layer EML3 to the second light emitting layer EML2 is easy and fast at a relatively low grayscale level, the exciton is excessively formed in a vicinity of the second light emitting layer EML2 adjacent to the second hole transport unit HTU2, and thus the red light efficiency is excessively increased. At a relatively high grayscale level, the exciton is mainly formed in a vicinity of the third light emitting layer EML3 adjacent to the second light emitting layer EML2. For example, from a low grayscale level (i. e., low grayscale value) to a high grayscale level (i. e., high grayscale value), the main position of the distribution of the exciton moves from the second light emitting layer EML2 to the third light emitting layer EML3. At this time, exciton quenching in which a light efficiency is reduced may occur due to mutual influence between the exciton of the second light emitting layer EML2 and the exciton of the third light emitting layer EML3. In this case, the roll-off phenomenon may intensify because a difference of the red light efficiency of the low grayscale level and the high grayscale level is large.

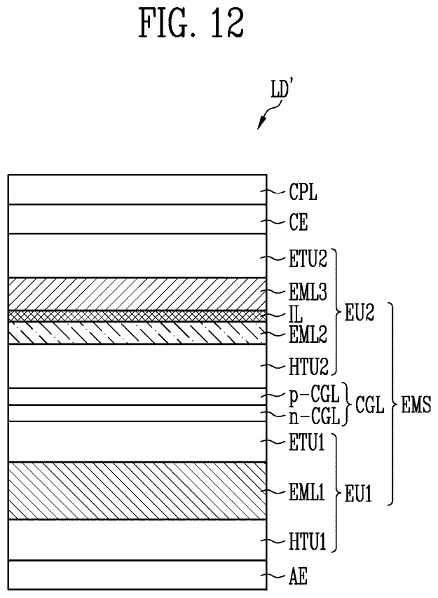

FIG. 12 is a diagram illustrating a light emitting element according to some embodiments. In FIG. 12, a description of a content (e.g., amount) overlapping that of FIG. 9 is omitted or simplified.

Referring to FIG. 12, the light emitting element LD′ may further include an intermediate layer IL. The intermediate layer IL may be included in the second light emitting unit EU2. The intermediate layer IL may be provided on the second light emitting layer EML2. More specifically, the intermediate layer IL may be provided between the second light emitting layer EML2 and the third light emitting layer EML3. The intermediate layer IL may block or reduce (or decrease) an electron injection from the third light emitting layer EML3 to the second light emitting layer EML2 while increasing a hole injection from the second light emitting layer EML2 to the third light emitting layer EML3.

In embodiments, the entire thickness of the second light emitting layer EML2, the intermediate layer IL, and the third light emitting layer EML3 may be 300 to 500 angstrom (Å), for example, about 410 to 430 Å.

In embodiments, a thickness of the intermediate layer IL may be 5 to 30 Å. In some embodiments, the thickness of the intermediate layer IL may be about 10 Å. Within the herein-described range, the roll-off phenomenon of the red light may be reduced by preventing or reducing the red light efficiency from rapidly increasing at the low grayscale level. In some embodiments, a sufficient red light efficiency may be secured without increasing a driving voltage.

In embodiments, the LUMO energy level of the intermediate layer IL may be higher (or shallower) than the LUMO energy level of the third light emitting layer EML3. In this case, the electron injection from the third light emitting layer EML3 to the second light emitting layer EML2 becomes difficult. In particular, as an excessive electron injection into the second light emitting layer EML2 is prevented or reduced at the low grayscale level, the red light efficiency may be prevented or reduced from rapidly increasing.

In embodiments, the LUMO energy level of the intermediate layer IL may be less than 1.5 electron volt (eV). If (e.g., when) the LUMO energy level of the intermediate layer IL is 1.5 eV or higher, the electron injection from the third light emitting layer EML3 to the second light emitting layer EML2 may be excessively reduced, and thus the red light efficiency may be excessively reduced. For example, within the herein-described range, the sufficient red light efficiency may be secured by preventing or reducing an excessive increase and decreases of the red light efficiency at the low grayscale level.

In embodiments, the intermediate layer IL may include a compound having at least one of a carbazole group and a triphenylamine group. In this case, the electron injection from the third light emitting layer EML3 to the second light emitting layer EML2 may be blocked (or reduced), and the hole injection from the second light emitting layer EML2 to the third light emitting layer EML3 may be performed smoothly. For example, the intermediate layer IL may include at least one compound represented by the following Formulas 1 to 4. Formula 1 is N-[1,1′-biphenyl]-4-yl-N-phenyl-3′-3-phenyl-9H-carbazol-9-yl-[1,1′-biphenyl]-4-amine, Formula 2 is N, N-di [1,1′-biphenyl]-4-yl-4′-9H-carbazol-9-yl-[1,1′-biphenyl]-4-amine, Formula 3 is N, N-di [1,1′-biphenyl]-4-yl-3′-9H-carbazol-9-yl-[1,1′-biphenyl]-4-amine, and Formula 4 is N-[1,1′-biphenyl]-4-yl-3′-9H-carbazol-9-yl-N-phenyl-[1,1′-biphenyl]-4-amine.

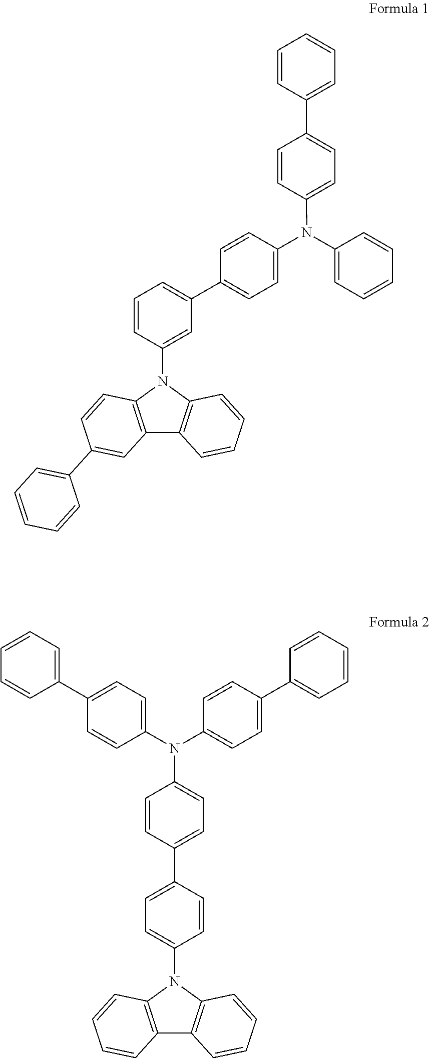 [SMILES: c1ccc(-c2ccc(N(c3ccccc3)c3ccc(-c4cccc(-n5c6ccccc6c6cc(-c7ccccc7)ccc65)c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

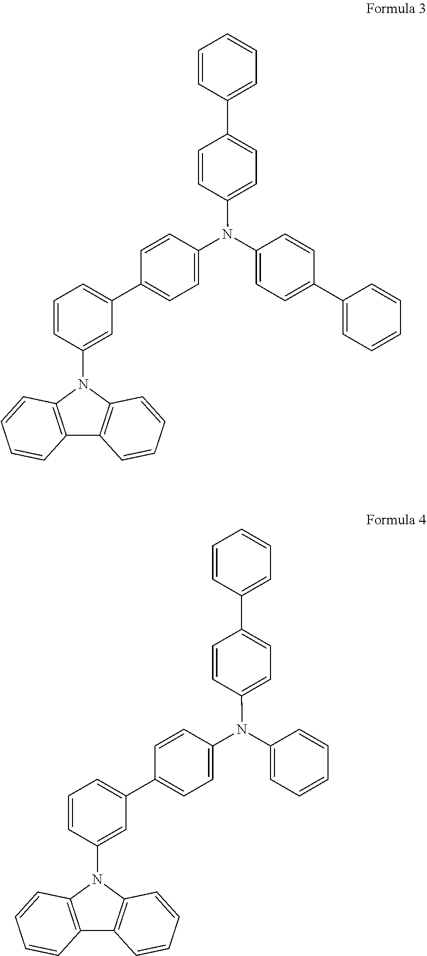 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccccc3)c3ccc(-c4cccc(-n5c6ccccc6c6ccccc65)c4)cc3)cc2)cc1]

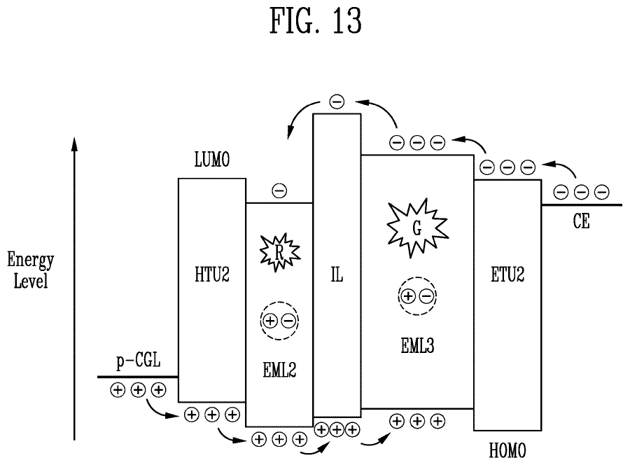

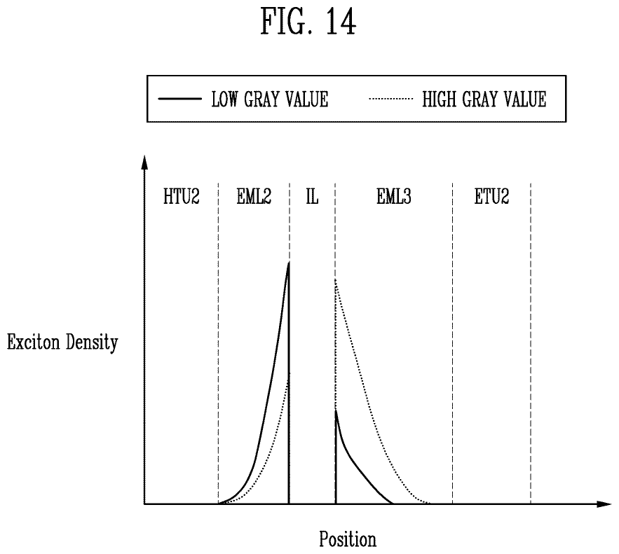

FIG. 13 is a diagram illustrating a light emission principle of the light emitting element of FIG. 12. In FIG. 13, components related to light emission of the second light emitting layer EML2 and the third light emitting layer EML3 are shown, and remaining components are omitted. FIG. 14 is a diagram illustrating a distribution of an exciton according to a position of the light emitting element of FIG. 12 for each grayscale level.

Referring to FIGS. 12 and 13, because the LUMO energy level of the intermediate layer IL is higher (or shallower) than the LUMO energy level of the third light emitting layer EML3, the electron injection from the third light emitting layer EML3 to the intermediate layer IL is reduced, and as a result, the electron injection to the second light emitting layer EML2 is reduced. In particular, as excessive electron injection to the second light emitting layer EML2 is prevented or reduced at the low grayscale level, an excessive increase of the red light efficiency may be prevented or reduced. As a result, because a degree to which the red light efficiency is reduced is reduced at the high grayscale level, the roll-off phenomenon may be improved.

Referring to FIG. 14, because the electron injection from the third light emitting layer EML3 to the second light emitting layer EML2 is prevented or reduced (or reduced) at the low grayscale level, the exciton is mainly formed in a vicinity of the second light emitting layer EML2 adjacent to the intermediate layer IL. In some embodiments, an amount of the exciton formed in the second light emitting layer EML2 is reduced, and thus the red light efficiency is reduced. At the high grayscale level, the exciton is mainly formed in a vicinity of the third light emitting layer EML3 adjacent to the intermediate layer IL. For example, from the low grayscale level to the high grayscale level, the main position of the distribution of the exciton moves from the second light emitting layer EML2 to the third light emitting layer EML3, but a degree of reduction in the efficiency of the red light due to exciton quenching is reduced due to the intermediate layer IL. Therefore, a difference in the red light efficiency between the low grayscale level and the high grayscale level may be reduced, thereby improving the roll-off phenomenon of the red light.

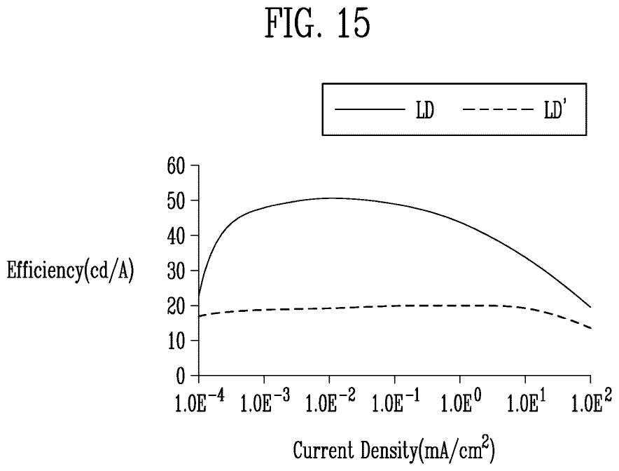

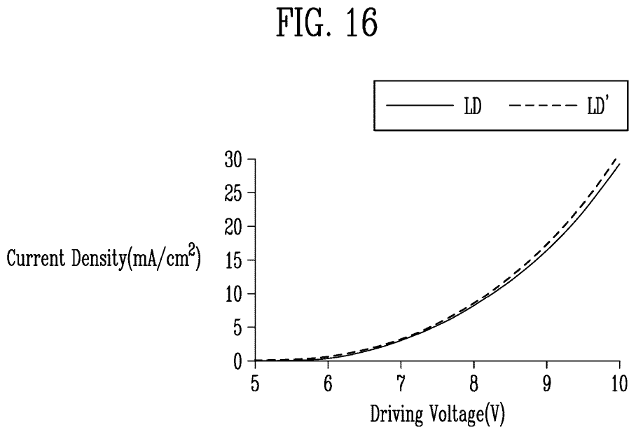

FIG. 15 is a diagram illustrating a red light efficiency according to a current density for each light emitting element. FIG. 16 is a diagram illustrating the current density according to a driving voltage for each light emitting element.

Referring to FIG. 15, in the light emitting element LD of FIG. 9, the electron is excessively injected into the second light emitting layer EML2 (refer to FIG. 10) at the relatively low grayscale level at which the current density is relatively low, and thus the red light efficiency is substantially or rapidly increased. On the other hand, the roll-off phenomenon occurs in which a degree to which the red light efficiency is substantially reduced as the grayscale level is in the relatively high grayscale level at which the current density is relatively high. In contrast, in the light emitting element LD′ of FIG. 12, the electron injection into the second light emitting layer EML2 (refer to FIG. 13) is blocked (or reduced) at the relatively low grayscale level at which the current density is relatively low, and thus the red light efficiency is not substantially or rapidly increased. Also, even though the grayscale level is the relatively high grayscale level at which the current density is relatively high, the roll-off phenomenon may be reduced or improved because the degree to which the red light efficiency is reduced is relatively small.

Referring to FIG. 16, the current density according to the driving voltage of the light emitting element LD of FIG. 9 and the light emitting element LD′ of FIG. 12 appears at a similar level. For example, if (e.g., when) utilizing the light emitting element LD′ including the intermediate layer IL (refer to FIG. 12), the roll-off phenomenon described herein may be reduced or improved and a sufficient current density may be secured without increasing the driving voltage.

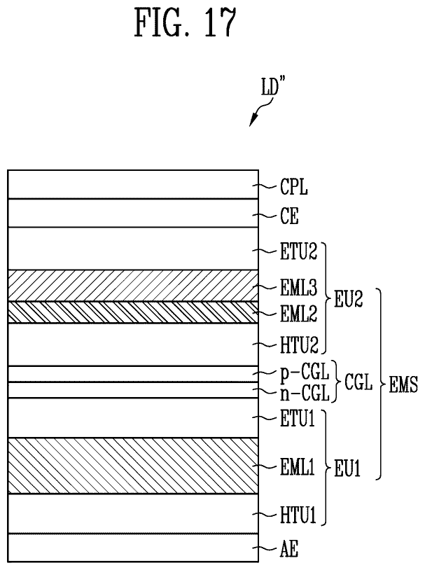

FIG. 17 is a diagram illustrating a light emitting element according to some embodiments. In FIG. 17, a description of a content (e.g., amount) overlapping that of FIG. 9 is omitted or simplified.

Referring to FIG. 17, differently from the light emitting element LD′ of FIG. 12, the light emitting element LD″ does not include the intermediate layer IL and includes the second light emitting layer EML2 different from the light emitting element LD of FIG. 9.

In embodiments, the second light emitting layer EML2 may include a red bipolar host and a red phosphorescent dopant. The red bipolar host may include at least one hole transport moiety and at least one electron transport moiety. For example, the red bipolar host may be an amphipathic host that has both (e.g., simultaneously) of a hole characteristic and an electronic characteristic. For example, the hole transport moiety may include an amine group, carbazole group, dibenzofuran group, dibenzothiophene group, fluorene group, and/or the like, and the electron transport moiety may include —F, cyano group, C₁-C₆₀ alkyl group substituted with —F or cyano group, C₆-C₆₀ aryl group substituted with —F or cyano group, π-electron deficient nitrogen-containing cyclic group, and/or the like, but the disclosure is not limited thereto. In this case, because electron acceptance performance of the second light emitting layer EML2 is reduced compared to a case where the second light emitting layer EML2 includes the red electron transport host (refer to FIG. 9), the electron injection into the second light emitting layer EML2 may be reduced.

In embodiments, the LUMO energy level of the red bipolar host may be higher (or shallower) than the LUMO energy level of the green electron transport host included in the third light emitting layer EML3. In this case, the LUMO energy level of the second light emitting layer EML2 becomes higher than the LUMO energy level of the third light emitting layer EML3, and thus the electron injection from the third light emitting layer EML3 to the second light emitting layer EML2 becomes difficult. In particular, as the excessive electron injection into the second light emitting layer EML2 is prevented or reduced at the relatively low grayscale level, the red light efficiency may be prevented or reduced from rapidly increasing.

In embodiments, the LUMO energy level of the red bipolar host may be less than 1.9 eV. If (e.g., when) the LUMO energy level of the red bipolar host is 1.9 eV or higher, the LUMO energy level of the second light emitting layer EML2 may become excessively high and the electron injection from the third light emitting layer EML3 to the second light emitting layer EML2 may be excessively reduced, and thus the red light efficiency may become excessively low. For example, within the herein-described range, a sufficient red light efficiency may be secured by preventing or reducing an excessive increases and decreases of the red light efficiency at the low grayscale.

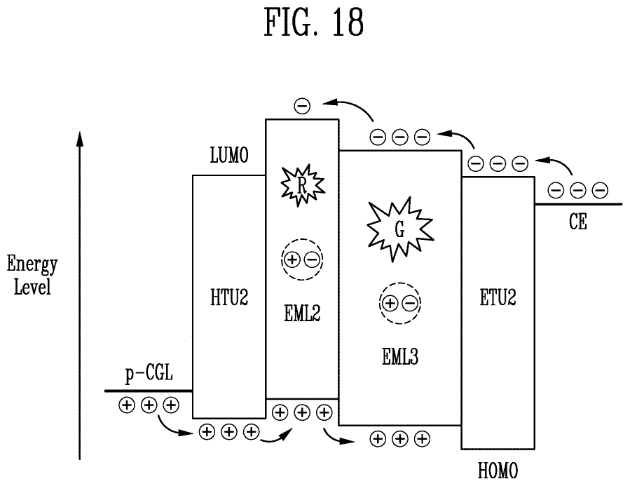

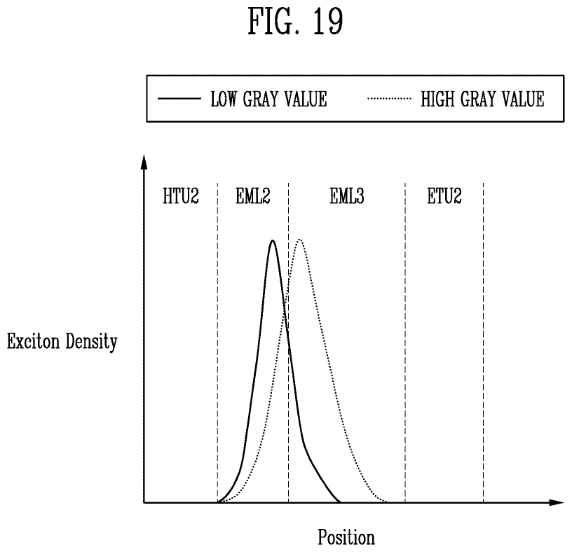

FIG. 18 is a diagram illustrating a light emission principle of the light emitting element of FIG. 17. In FIG. 18, components related to light emission of the second light emitting layer EML2 and the third light emitting layer EML3 are shown, and remaining components are omitted. FIG. 19 is a diagram illustrating the distribution of the exciton according to a position of the light emitting element of FIG. 17 for each grayscale level.

Referring to FIGS. 17 and 18, because the LUMO energy level of the second light emitting layer EML2 is higher (or shallower) than the LUMO energy level of the third light emitting layer EML3, the electron injection from the third light emitting layer EML3 to the second light emitting layer EML2 is reduced. In particular, as excessive electron injection to the second light emitting layer EML2 is prevented or reduced at the relatively low grayscale level, an excessive increase of the red light efficiency may be prevented or reduced. As a result, because a degree to which the red light efficiency is reduced is reduced at the relatively high grayscale level, the roll-off phenomenon may be reduced or improved.

Referring to FIG. 19, because the electron injection from the third light emitting layer EML3 to the second light emitting layer EML2 is blocked (or reduced) at the relatively low grayscale level, the exciton is mainly formed in the vicinity of the second light emitting layer EML2 adjacent to the third light emitting layer EML3. In some embodiments, an amount of the exciton is reduced, and thus the red light efficiency is reduced. At the relatively high grayscale level, the exciton is mainly formed in the vicinity of the third light emitting layer EML3 adjacent to the second light emitting layer EML2. For example, from the low grayscale level to the high grayscale level, the main position of the distribution of the exciton moves from the second light emitting layer EML2 to the third light emitting layer EML3, exciton quenching occurs, and thus the red light efficiency is reduced. In this case, because the red light efficiency is small at the relatively low grayscale level, the difference in the red light efficiency between the relatively low grayscale level and the relatively high grayscale level may be reduced, thereby improving the roll-off phenomenon of the red light.

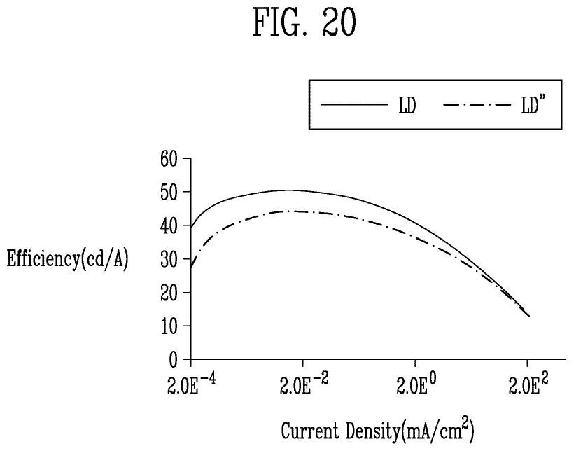

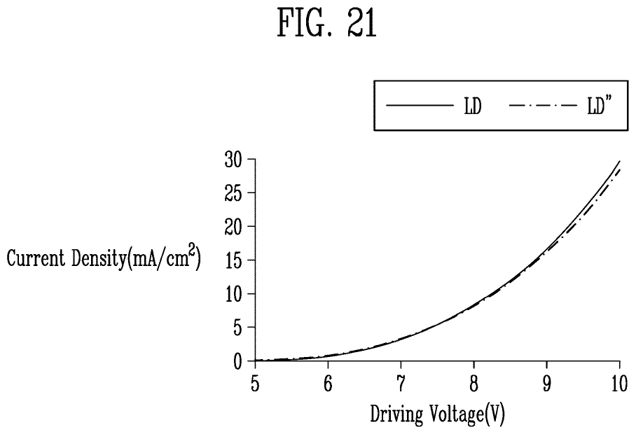

FIG. 20 is a diagram illustrating the red light efficiency according to the current density for each light emitting element. FIG. 21 is a diagram illustrating the current density according to the driving voltage for each light emitting element.

Referring to FIG. 20, in the light emitting element LD of FIG. 9, the electron is excessively injected into the second light emitting layer EML2 (refer to FIG. 10) at the low grayscale level at which the current density is low, and thus the red light efficiency is rapidly increased. Accordingly, the occurrence of the roll-off phenomenon in which a degree to which the red light efficiency is substantially or largely reduced as the grayscale level is the relatively high grayscale level at which the current density is high. In contrast, in the light emitting element LD″ of FIG. 17, the electron injection into the second light emitting layer EML2 (refer to FIG. 18) is blocked (or reduced) at the relatively low grayscale level at which the current density is low, and thus the red light efficiency is not rapidly increased. Therefore, even though the grayscale is the relatively high grayscale level at which the current density is high, the roll-off phenomenon may be reduced or improved because the degree to which the red light efficiency is reduced is small.

Referring to FIG. 21, the current density according to the driving voltage of the light emitting element LD of FIG. 9 and the light emitting element LD″ of FIG. 17 appears at a similar level. For example, if (e.g., when) utilizing the light emitting element LD″ including the second light emitting layer EML2 (refer to FIG. 17) including the red bipolar host, the roll-off phenomenon described herein may be reduced or improved and a sufficient current density may be secured without increasing the driving voltage.

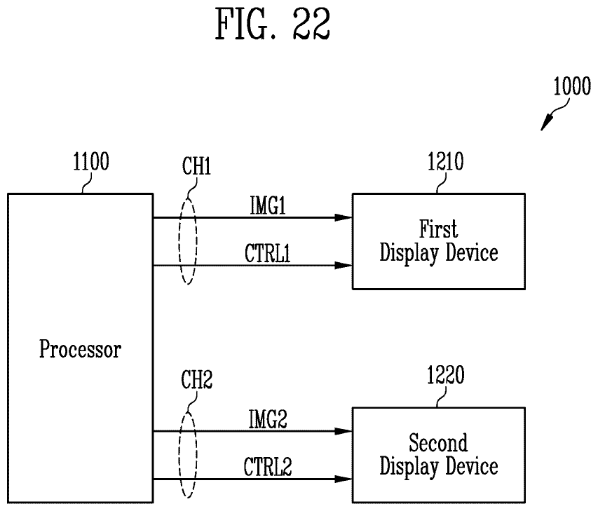

FIG. 22 is a diagram illustrating a display system according to some embodiments.

Referring to FIG. 22, the display system 1000 may include a processor 1100 and one or more display devices 1210 and 1220.

The processor 1100 may perform one or more suitable tasks and calculations. In embodiments, the processor 1100 may include an application processor, a graphic processor, a microprocessor, a central processing unit (CPU), and/or the like. The processor 1100 may be connected to other components of the display system 1000 through a bus system and control the other components.

In FIG. 22, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may be to transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may be to transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and control signal CTRL of FIG. 1, respectively.

The display system 1000 may include at least one selected from among a computing system providing an image display function, such as a portable computer, a mobile phone, a smart phone, a tablet personal computer, a smart watch, a watch phone, a portable multimedia player (PMP), a navigation device, an ultra mobile personal computer (UMPC), and one or more combinations thereof. In some embodiments, the display system 1000 may include at least one of a head mounted display (HMD) device, a virtual reality (VR) device, a mixed reality (MR) device, and an augmented reality (AR) device.

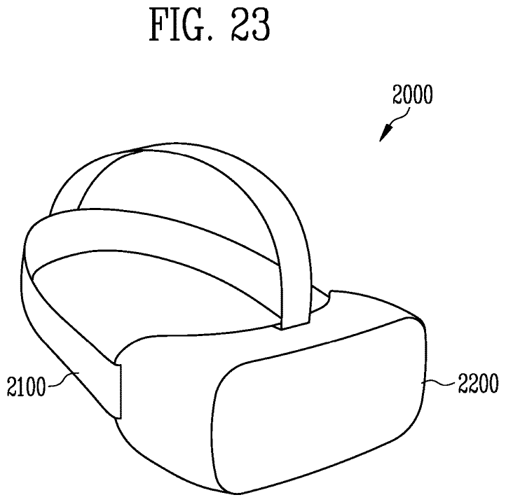

FIG. 23 is a diagram illustrating an application example of the display system of FIG. 22.

Referring to FIG. 23, the display system 1000 of FIG. 22 may be applied to a head mounted display device 2000. The head mounted display device 2000 may be a wearable electronic device that may be worn on a user's head.

The head mounted display device 2000 may include a head mount band 2100 and a display device storage case 2200. The head mount band 2100 may be connected to the display device storage case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, and/or the like.

The display device storage case 2200 may accommodate the first and second display devices 1210 and 1220 of FIG. 22. The display device storage case 2200 may further accommodate the processor 1100 of FIG. 22.

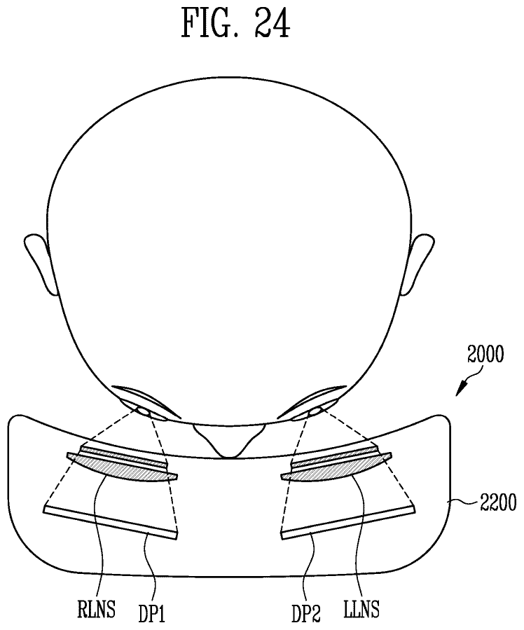

FIG. 24 is a diagram illustrating the head mounted display device worn by a user of FIG. 23.

Referring to FIG. 24, a first display panel DP1 of the first display device 1210 (see FIG. 22) and a second display panel DP2 of the second display device 1220 (see FIG. 22) are provided in the head mounted display device 2000. The head mounted display device 2000 may further include one or more lenses LLNS and RLNS.

Within the display device storage case 2200, the right eye lens RLNS may be provided between the first display panel DP1 and a user's right eye. Within the display device storage case 2200, the left eye lens LLNS may be provided between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective sub-areas and may be viewed to the user.

### EXAMPLES

### Comparative Example 1

A light emitting element LD1 of Comparative Example 1 did not include the intermediate layer IL. In some embodiments, the second light emitting layer EML2 included the red hole transport host, the red electron transport host, and the red phosphorescent dopant, and the thickness of the second light emitting layer EML2 was 50 angstrom (Å). In some embodiments, the third light emitting layer EML3 included the green hole transport host, the green electron transport host, and the green phosphorescent dopant, and the thickness of the third light emitting layer EML3 was 350 Å.

### Comparative Example 2

A light emitting element LD2 of Comparative Example 2 was the same as the light emitting element LD1 of Comparative Example 1, except that the second light emitting layer EML2 included the red fluorescent dopant and the third light emitting layer EML3 included the green fluorescent dopant.

### Embodiment 1

A light emitting element LD1′ of Embodiment 1 was the same as the light emitting element LD1 of Comparative Example 1, except that the light emitting element LD1′ of Embodiment 1 included the intermediate layer IL, and the intermediate layer IL included the compound F1 represented by Formula 1 herein, and the thickness of the intermediate layer IL was 30 Å.

### Embodiment 2

A light emitting element LD2′ of Embodiment 2 was the same as the light emitting element LD1′ of Embodiment 1, except that the intermediate layer IL included the compound F2 represented by Formula 2 herein.

### Embodiment 3

A light emitting element LD3′ of Embodiment 3 was the same as the light emitting element LD1′ of Embodiment 1, except that the intermediate layer IL included the compound F3 represented by Formula 3 herein.

### Embodiment 4

A light emitting element LD4′ of Embodiment 4 was the same as the light emitting element LD3′ of Embodiment 3, except that the thickness of the intermediate layer IL was 20 Å.

### Embodiment 5

A light emitting element LD5′ of Embodiment 5 was the same as the light emitting element LD3′ of Embodiment 3, except that the thickness of the intermediate layer IL was 10 Å.

### Embodiment 6

A light emitting element LD6′ of Embodiment 6 was the same as the light emitting element LD5′ of Embodiment 5, except that the thickness of the second light emitting layer EML2 was 80 Å and the thickness of the third light emitting layer EML3 was 320 Å.

### Embodiment 7

A light emitting element LD7′ of Embodiment 7 was the same as the light emitting element LD5′ of Embodiment 5, except that the thickness of the second light emitting layer EML2 was 100 Å and the thickness of the third light emitting layer EML3 was 300 Å.

### Embodiment 8

The light emitting element LD″ of Embodiment 8 was the same as the light emitting element LD1 of Comparative Example 1, except that the second light emitting layer EML2 included the red bipolar host, the thickness of the second light emitting layer EML2 was 70 Å, and the thickness of the third light emitting layer EML3 was 330 Å.

### Evaluation Example

Table 1 illustrates driving voltage, efficiency, and roll-off of the light emitting elements of Comparative Examples 1 to 2 and Embodiments 1 to 8 at the low grayscale level.

TABLE 1

| | | | Second light emitting | | | Third light emitting | | |
|---|---|---|---|---|---|---|---|---|
| | | | layer | | | layer | | |
| | | Second light emitting | Driving | | Roll- | Driving | | Roll- |
| | Intermediate | layer/Third light | voltage | Efficiency | off | voltage | Efficiency | off |
| No | layer | emitting layer | (V) | (cd/A) | (%) | (V) | (cd/A) | (%) |
| Comparative | — | Phosphorescence | 100% | 100% | 100% | 100% | 100% | 100% |
| Example 1 | | EML2(50 Å)/ | | | | | | |
| (LD1) | | EML3(350 Å) | | | | | | |
| Comparative | — | Fluorescence | 120% | 70% | 85% | 130% | 65% | 80% |
| Example 2 | | EML2(50 Å)/ | | | | | | |
| (LD2) | | EML3(350 Å) | | | | | | |
| Embodiment 1 | F1(30 Å) | Phosphorescence | 115% | 96% | 80% | 112% | 96% | 83% |
| (LD1′) | | EML2(50 Å)/ | | | | | | |
| | | EML3(350 Å) | | | | | | |
| Embodiment 2 | F2(30 Å) | Phosphorescence | 118% | 95% | 78% | 113% | 97% | 79% |
| (LD2′) | | EML2(50 Å)/ | | | | | | |
| | | EML3(350 Å) | | | | | | |
| Embodiment 3 | F3(30 Å) | Phosphorescence | 115% | 95% | 75% | 110% | 94% | 75% |
| (LD3′) | | EML2(50 Å)/ | | | | | | |
| | | EML3(350 Å) | | | | | | |
| Embodiment 4 | F3(20 Å) | Phosphorescence | 111% | 97% | 82% | 106% | 98% | 88% |
| (LD4′) | | EML2(50 Å)/ | | | | | | |
| | | EML3(350 Å) | | | | | | |
| Embodiment 5 | F3(10 Å) | Phosphorescence | 100% | 100% | 86% | 100% | 102% | 98% |
| (LD5′) | | EML2(50 Å)/ | | | | | | |
| | | EML3(350 Å) | | | | | | |
| Embodiment 6 | F3(10 Å) | Phosphorescence | 114% | 96% | 80% | 108% | 97% | 94% |
| (LD6′) | | EML2(80 Å)/ | | | | | | |
| | | EML3(320 Å) | | | | | | |
| Embodiment 7 | F3(10 Å) | Phosphorescence | 117% | 93% | 78% | 113% | 95% | 92% |
| (LD7′) | | EML2(100 Å)/ | | | | | | |
| | | EML3(300 Å) | | | | | | |
| Embodiment 8 | — | Phosphorescence | 90% | 110% | 96% | 105% | 95% | 95% |
| (LD″) | | EML2(70 Å)/ | | | | | | |
| | | EML3(330 Å) | | | | | | |

Referring to Table 1, it may be seen that the light emitting element LD2 of Comparative Example 2 has an improved roll-off phenomenon of the red light compared to the light emitting element LD1 of Comparative Example 1, but exhibits a driving voltage that is very high and the red light efficiency is very low (e.g., 70%). It may be seen that the roll-off phenomenon of the red light is improved in the light emitting elements of Embodiments 1 to 8 without a significant change in the driving voltage and the red light efficiency compared to the light emitting element LD1 of Comparative Example 1. In particular, it may be seen that the roll-off phenomenon of the red light is improved while the light emitting element LD5′ of Embodiment 5 concurrently (e.g., simultaneously) maintains the same red light efficiency and high green light efficiency compared to the light emitting element LD1 of Comparative Example 1 at the same driving voltage.

Although the disclosure has been described according to the herein-described embodiments, it should be noted that the herein-described embodiments are for describing the disclosure and not for limiting the scope of the disclosure. Those of ordinary skill in the art to which the disclosure pertains will understand that one or more suitable modifications are possible within the scope of the technical spirit of the disclosure.

The scope of the disclosure is not limited to the details described in the detailed description of the specification, but should also be defined by the claims, and equivalents thereof. It is to be construed that all changes or modifications derived from the meaning and scope of the claims and equivalent concepts thereof are included in the scope of the disclosure.

What is claimed:

1. A light emitting element comprising:
an anode;
a cathode facing the anode; and
a light emitting structure between the anode and the cathode, and comprising a first light emitting unit, a charge generation layer, and a second light emitting unit,
wherein the second light emitting unit comprises:
a second hole transport unit on the charge generation layer;
a second light emitting layer on the second hole transport unit;
an intermediate layer on the second light emitting layer;
a third light emitting layer on the intermediate layer; and
a second electron transport unit between the third light emitting layer and the cathode.

2. The light emitting element according to claim 1, wherein the first light emitting unit comprises:
a first hole transport unit on the anode;
a first electron transport unit facing the first hole transport unit and adjacent to the charge generation layer; and
a first light emitting layer between the first hole transport unit and the first electron transport unit.

3. The light emitting element according to claim 1, wherein an entire thickness of the second light emitting layer, the intermediate layer, and the third light emitting layer is 300 angstrom (Å) to 500 Å.

4. The light emitting element according to claim 1, wherein a thickness of the intermediate layer is 5 angstrom (Å) to 30 Å.

5. The light emitting element according to claim 1, wherein a lowest unoccupied molecular orbital (LUMO) energy level of the intermediate layer is higher than a LUMO energy level of the third light emitting layer.

6. The light emitting element according to claim 5, wherein the lowest unoccupied molecular orbital (LUMO) energy level of the intermediate layer is less than 1.5 electron volt (eV).

7. The light emitting element according to claim 1, wherein the intermediate layer comprises a compound having at least one of a carbazole group and a triphenylamine group.

8. The light emitting element according to claim 1, wherein the first light emitting unit comprises a first light emitting layer,
the first light emitting layer is configured to emit blue light,
the second light emitting layer is configured to emit red light, and
the third light emitting layer is configured to emit green light.

9. The light emitting element according to claim 8, wherein the first light emitting layer comprises a blue fluorescent host and a blue fluorescent dopant.

10. The light emitting element according to claim 8, wherein the second light emitting layer comprises a red hole transport host, a red electron transport host, and a red phosphorescent dopant, and
the third light emitting layer comprises a green hole transport host, a green electron transport host, and a green phosphorescent dopant.

11. The light emitting element according to claim 1, wherein the charge generation layer comprises:
an n-type charge generation layer adjacent to the first light emitting unit; and
a p-type charge generation layer adjacent to the second light emitting unit.

12. The light emitting element according to claim 1, further comprising:
a capping layer on the cathode.

13. A light emitting element comprising:
an anode;
a cathode facing the anode; and
a light emitting structure between the anode and the cathode, and comprising a first light emitting unit, a charge generation layer, and a second light emitting unit,
wherein the second light emitting unit comprises:
a second hole transport unit on the charge generation layer;
a second electron transport unit facing the second hole transport unit and adjacent to the cathode; and
a second light emitting layer and a third light emitting layer between the second hole transport unit and the second electron transport unit, and
the second light emitting layer comprising a red bipolar host and a red phosphorescent dopant.

14. The light emitting element according to claim 13, wherein the second light emitting layer is between the second hole transport unit and the third light emitting layer, and the third light emitting layer is between the second light emitting layer and the second electron transport unit.

15. The light emitting element according to claim 13, wherein the third light emitting layer comprises a green hole transport host, a green electron transport host, and a green phosphorescent dopant.

16. The light emitting element according to claim 15, wherein a lowest unoccupied molecular orbital (LUMO) energy level of the red bipolar host is higher than a LUMO energy level of the green electron transport host.

17. The light emitting element according to claim 16, wherein the LUMO energy level of the red bipolar host is less than 1.9 eV.

18. The light emitting element according to claim 13, wherein the first light emitting unit comprises:
a first hole transport unit on the anode;
a first electron transport unit facing the first hole transport unit and adjacent to the charge generation layer; and
a first light emitting layer between the first hole transport unit and the first electron transport unit.

19. A display device comprising the light emitting element of claim 1.

20. The display device according to claim 19, wherein the display device comprises at least one of a flat display, a curved display, a flexible display, a rollable display, a foldable display, a stretchable display, a head-up display, a head-mounted display, a wearable display, a micro display, a 3D display, a virtual reality display, an augmented reality display, and a mixed reality display.
